(19) United States
(12) Patent Application Publication
(10) Pub. No.: US 2024/0393511 A1
(43) Pub. Date: Nov. 28, 2024

(54) COLOR FILM SUBSTRATE, DISPLAY SUBSTRATE AND DISPLAY APPARATUS

(71) Applicants: Hefei Xinsheng Optoelectronics Technology Co., Ltd., Hefei, Anhui (CN); BOE Technology Group Co., Ltd., Beijing (CN)

(72) Inventors: Yanchun Lu, Beijing (CN); Yongcan Wang, Beijing (CN); Ya Yu, Beijing (CN); Mingfei Zhang, Beijing (CN); Shenwei Shi, Beijing (CN)

(73) Assignees: Hefei Xinsheng Optoelectronics Technology Co., Ltd., Hefei, Anhui (CN); BOE Technology Group Co., Ltd., Beijing (CN)

(21) Appl. No.: 18/271,673

(22) PCT Filed: Sep. 29, 2022
(86) PCT No.: PCT/CN2022/122786

§ 371 Date: Jul. 11, 2023

(51) Int. Cl. G02B 5/20; G02B 5/00; H01L 27/12

(52) U.S. Cl. CPC G02B 5/201; G02B 5/003; H01L 27/124

(57) ABSTRACT

A color film substrate, a display substrate and a display apparatus are provided in embodiments of the present disclosure. The color film substrate includes a substrate base plate and a black matrix layer. There are an irregular-shaped active area and a peripheral region surrounding the irregular-shaped active area on the substrate base plate. The irregular active area includes a plurality of first pixels and at least one second pixel, and the second pixel is closer to the peripheral region relative to the first pixels, and a shape of a boundary line of each second pixel close to the peripheral region is the same as a shape of a boundary line of the peripheral region. The black matrix layer includes a plurality of shielding structures, at least one of the plurality of shielding structures shields second pixel in a single-domain manner or at its circumference to form an opening region.

### TECHNICAL FIELD

The present disclosure relates to the technical field of display devices and, more particularly, to a color film substrate, a display substrate and a display apparatus.

### BACKGROUND

With continuous development of display apparatus, people's display requirements for the display apparatus are increasingly improved. An active area of a color film substrate included in many display apparatuses is an irregular-shaped active area, in which a boundary of the active area is presented with a design of an irregular shape or a rounded corner to adapt to different application scenarios of the display apparatuses.

At present, a contour at a position of the irregular shape or the rounded corner of the active area of the color film substrate is shielded by a black matrix layer, and gray-scale transition is realized at an edge of the contour.

However, at present, when the black matrix layer is used to shield a pixel corresponding to the position of the irregular shape or the rounded corner in the active area, a shielding mode that an upper domain and a lower domain of the pixel are both partially shielded is usually used, so that an opening region formed by the pixel is distributed at both sides of the pixel. In this way, when the pixel is arranged in a row direction, the black matrix in a middle portion of the pixel is also arranged in the row direction, thus resulting in burrs visually at the position of the irregular shape or the rounded corner of the active area of the color film substrate, which affects display effect of the color film substrate.

### SUMMARY

A color film substrate, a display substrate and a display apparatus are provided in embodiments of the present disclosure, to solve a problem that burrs occur at a position of an irregular shape or a rounded corner of an active area of a color film substrate in related art.

In order to solve above technical problems, the present disclosure is realized as follows.

In a first aspect, a color film substrate is provided in an embodiment of the present disclosure, which includes:
a substrate base plate with an irregular-shaped active area and a peripheral region surrounding the irregular-shaped active area;
the irregular-shaped active area including a plurality of first pixels and at least one second pixel, wherein the second pixel is closer to the peripheral region relative to the plurality of first pixels, and a shape of a boundary line of each second pixel close to the peripheral region is the same as a shape of a boundary line of the peripheral region; and
a black matrix layer including a plurality of shielding structures, at least one of the plurality of shielding structures shielding the second pixel in a single-domain manner or at the circumference to form an opening region;
when the shielding structure shields the second pixel in the single-domain manner, an area of the opening region formed by the second pixel is greater than half an area of the second pixel; and
when the shielding structure shields the second pixel at the circumference, the opening region formed by the second pixel is concentrated in a middle portion of the second pixel.

Optionally, the second pixel includes a plurality of first sub-pixels, at least one of the plurality of first sub-pixels being an irregular-shaped sub-pixel, and with the shielding structure shielding the plurality of first sub-pixels in the single-domain manner, areas of opening regions formed by each of the first sub-pixel are equal.

Optionally, an overlapping part of a projection of the shielding structure on the substrate base plate in a first direction and a projection of the irregular-shaped sub-pixel on the color film substrate in the first direction is a first pattern, and an area of the first pattern is less than half an area of the irregular-shaped sub-pixel.

Optionally, the overlapping part of the projection of the shielding structure on the substrate base plate in the first direction and the projection of the irregular-shaped sub-pixel on the color film substrate in the first direction is a shielded part, and areas of shielded parts of the irregular-shaped sub-pixels at different positions of the irregular-shaped active area are different, wherein the shielded position is a position of the irregular-shaped sub-pixel at either side of a centerline in a row direction of pixels.

Optionally, the irregular-shaped active area is provided with a blind hole; and
the blind hole is arranged close to the peripheral region, and the plurality of second sub-pixels is arranged around the blind hole.

Optionally, the blind hole includes a first part, a second part and a third part, and the black matrix layer at least includes a first shielding structure, a second shielding structure and a third shielding structure;
the second part is located between the first part and the third part, and the first part is close to the peripheral region;
the first shielding structure shields the second sub-pixel disposed around the first part to form a first opening region, the second shielding structure shields the second sub-pixel disposed around the second part to form a second opening region, and the third shielding structure shields the second sub-pixel disposed around the second part to form a third opening region; and
the first opening region is located at a side of the second sub-pixel close to the peripheral region, the third opening region is located at a side of the second sub-pixel close to the peripheral region, and the second opening region is located in a middle portion of the second sub-pixel.

Optionally, an area of the first part is equal to an area of the second part.

Optionally, the first part and the second part are both of a fan-shaped structure, and a central angle of the first part and a central angle of the second part are both between 76° and 90°.

Optionally, the second pixel includes a plurality of first sub-pixels, at least one of the plurality of first sub-pixels is an irregular-shaped sub-pixel, and with the shielding structure shielding the plurality of first sub-pixels at the circumference, areas of opening regions formed by each of the first sub-pixels are equal.

Optionally, a width of the opening region formed by the shielding structure shielding the second sub-pixel is less than 10 microns, wherein the width of the opening region is a size of the opening area along a column direction of the second sub-pixel.

Optionally, at least a part of a boundary of the irregular-shaped active area is an arc, and a boundary line adjacent to the arc is tangent to the arc.

Optionally, the color film substrate further includes a signal line; and
the signal line is connected to each of the second sub-pixels in the color film substrate.

Optionally, the signal line includes a plurality of data lines and a plurality of gate lines; and
each of the plurality of data lines is connected to a column of the second sub-pixels, and each of the plurality of gate lines is connected to a row of the second sub-pixels.

Optionally, at least one of the plurality of data lines is in a bent shape, and at least one of the column of the second sub-pixels connected to the data line in the bent shape is the irregular-shaped sub-pixel.

Optionally, at least one of the plurality of gate lines is in a bent shape, and at least one of the row of the second sub-pixels connected to the gate line in the bent shape is the irregular-shaped sub-pixel.

Optionally, the data line includes a touch signal line; and
the touch signal line is connected in a target second sub-pixel included in the second pixel, wherein the target second sub-pixel is a blue sub-pixel.

In a second aspect, a display substrate is provided in an embodiment of the present disclosure, including the color film substrate mentioned in the first aspect.

In a third aspect, a display apparatus is provided in an embodiment of the present disclosure, including the display substrate mentioned in the second aspect.

It can be seen from the above-described embodiments that in the embodiments of the present disclosure, the auxiliary signal transmission layer is arranged on at least one surface of the source and drain metal layer, the source and drain metal layer includes the first signal line and the second signal line, and the auxiliary signal transmission layer includes the third signal line and the fourth signal line, and the third signal line and the first signal line are overlapped and the fourth signal line and the second signal line are overlapped, and thus when the first signal line or the second signal line is disconnected due to foreign matter generated in a deposition process of the source and drain metal layer, the signal can be continuously transmitted through the third signal line overlapped with the first signal line and through the fourth signal line overlapped with the second signal line, so that the signal can be continuously transmitted, thereby occurrence of poor signal conduction caused by the foreign matter is reduced to a certain extent and display effect of the color film substrate is ensured.

### BRIEF DESCRIPTION OF THE DRAWINGS

In order to explain embodiments of the present disclosure or the technical scheme in the prior art more clearly, the drawings required in the description of the embodiments or the prior art will be briefly introduced below; obviously, the drawings in the following description are some embodiments of the present disclosure, and other drawings can be obtained according to these drawings by those of ordinary skill in the art without paying creative labor.

FIG. 1 is a schematic diagram of pixel distribution of a color film substrate according to an embodiment of the present disclosure;

FIG. 2 shows a schematic structural diagram of a cross-section of a color film substrate according to an embodiment of the present disclosure;

FIG. 3 is a schematic diagram of pixel distribution of a color film substrate according to an embodiment of the present disclosure in an area A of FIG. 1;

FIG. 4 is a schematic diagram of pixel distribution of a color film substrate according to an embodiment of the present disclosure in an area B of FIG. 1;

FIG. 5 is a schematic diagram of pixel distribution of a color film substrate according to an embodiment of the present disclosure in an area C of FIG. 1;

FIG. 6 is a schematic diagram of pixel distribution of a color film substrate according to an embodiment of the present disclosure in an area D of FIG. 1;

FIG. 7 is a schematic diagram showing an area change of an opening region formed by a second sub-pixel of the color film substrate in the area A and the area B of FIG. 1 according to the embodiment of the present disclosure;

FIG. 8 is a schematic diagram showing an area change of an opening region formed by a second sub-pixel of the color film substrate in the area C and the area D of FIG. 1 according to the embodiment of the present disclosure;

FIG. 9 is a schematic diagram showing distribution of an opening region formed after a pixel of a color film substrate is shielded in a single-domain manner according to an embodiment of the present disclosure;

FIG. 10 is a schematic diagram showing distribution of an opening region formed after circumference of a pixel of a color film substrate is shielded according to an embodiment of the present disclosure;

FIG. 11 is a schematic diagram showing regional distribution of blind holes of a color film substrate according to an embodiment of the present disclosure; and

FIG. 12 is a schematic diagram showing distribution of signal lines of a color film substrate according to an embodiment of the present disclosure.

### REFERENCE NUMERALS

1. Substrate base plate; 2. Irregular-shaped active area; 3: Peripheral region; 4: Black matrix layer; 5: Blind hole; 6: Signal line; 21: First pixel; 22: Second pixel; 51: First part; 52: Second part; 53: Third part; 61: Data line; 62: Gate line; 201: Open region; 221: First sub-pixel.

### DETAILED DESCRIPTION

The technical solutions may be clearly and completely described below with reference to the drawings according to the embodiments of the present disclosure. Apparently, the described embodiments are merely certain embodiments of the present disclosure, rather than all of the embodiments. All of the other embodiments that a person skilled in the art obtains on the basis of the embodiments of the present disclosure fall within the protection scope of the present disclosure.

Unless the context requires otherwise, a term “comprise” and variations thereof, such as “comprises” and “comprising”, are interpreted as an open and inclusive meaning, that is, “including, but not limited to” throughout the specification and claims. In description of the specification, terms “one embodiment”, “some embodiments”, “exemplary embodiments”, “an example”, “a specific example” or “some examples” are intended to indicate that a specific feature, structure, material or characteristic related to this embodiment or example is included in at least one of embodiments or examples of this disclosure. Schematic representations of the above terms do not necessarily refer to a same embodiment or example. Furthermore, the specific features, structures, materials or characteristics described may be included in any one or more of the embodiments or examples in any suitable way.

In the following, terms “first” and “second” are only used for descriptive purposes, and cannot be understood as indicating or implying relative importance or implicitly indicating a number of indicated technical features. Therefore, features defined with “first” and “second” may include one or more of these features explicitly or implicitly. In the description of embodiments of the present disclosure, “plural” means two or more, unless otherwise specified.

In describing some embodiments, an expression “electrically connected” and its derivatives may be used. For example, in describing some embodiments, the term “electrically connected” may be used to indicate that two or more components are in direct physical contact or electrical contact with each other.

“A and/or B” includes following three combinations: A alone, B alone, and combination of A and B.

Use of “configured as” in this document means an open and inclusive language, which does not exclude devices suitable for or configured to perform additional tasks or steps.

As used herein, “approximately” includes a stated value as well as an average value within an acceptable deviation range from a specific value, and the acceptable deviation range is determined by a person of ordinary skilled in the art in consideration of measurement in question and error associated with the measurement of a specific quantity (i.e., limitations of the measurement system).

“Same layer” herein refers to a layer structure formed by forming a film layer for forming a specific pattern using a same film forming process, which is then subjected to one patterning process using a same mask. Depending on specific patterns, the one patterning process may include multiple exposure, development or etching processes, and specific patterns in the formed layer structure may be continuous or discontinuous, and these specific patterns may also be at different heights or have different thicknesses. On the contrary, “different layers” refers to a layer structure formed by forming a film layer for a specific pattern using corresponding film-forming processes, which is then subjected to patterning processes using corresponding masks. For example, “two layer structures being disposed in different layers” means that two layer structures are formed in corresponding processing steps (a film-forming process and a patterning process) respectively.

Exemplary embodiments are described herein with reference to cross-sectional views and/or plan views as idealized exemplary drawings. In the drawings, thicknesses of layers and regions are exaggerated for clarity. Therefore, variations in shape relative to the drawings due to, for example, manufacturing techniques and/or tolerances can be conceived. Therefore, the exemplary embodiments should not be interpreted as limited to shapes of the regions shown herein, but include shape deviations caused by, for example, manufacturing. For example, an etched region shown as a rectangle will generally have a curved feature. Therefore, regions shown in the drawings are schematic in nature, and their shapes are not intended to show actual shapes of the regions of the device, and are not intended to limit scopes of the exemplary embodiments.

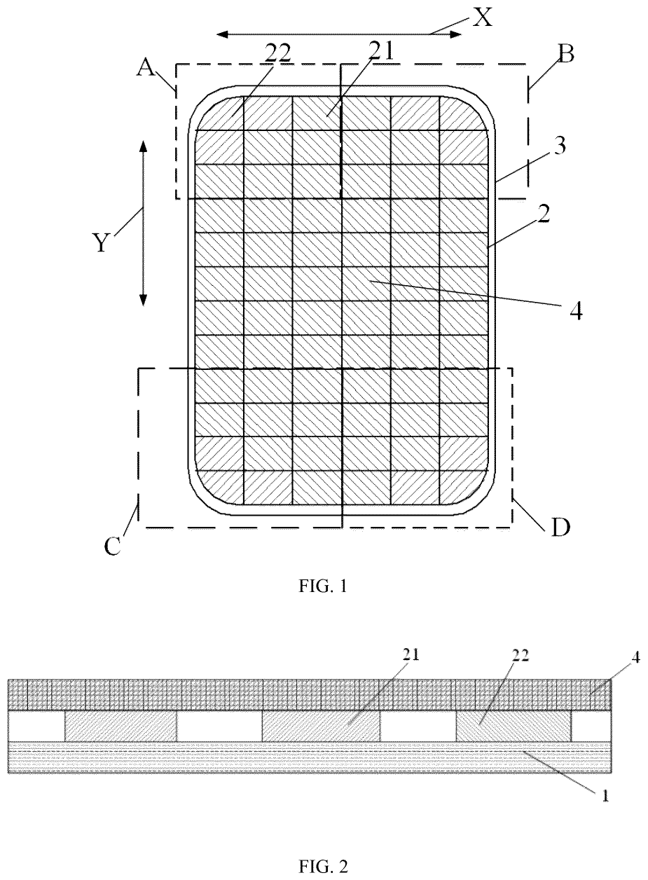

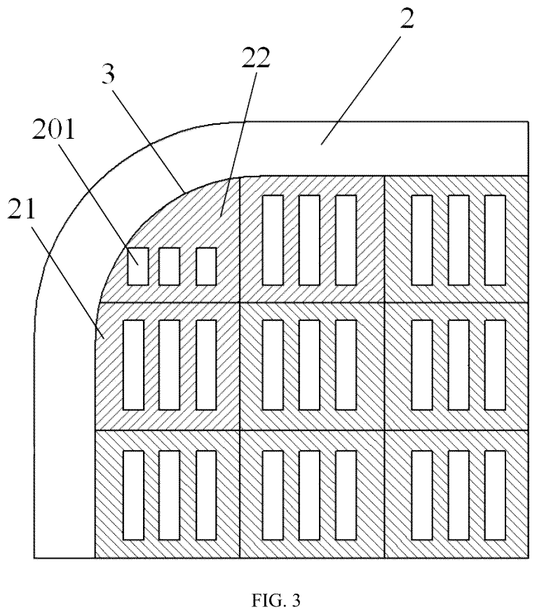

In a first aspect, a color film substrate is provided in an embodiment of the present disclosure. FIG. 1 is a schematic diagram of pixel distribution of a color film substrate according to an embodiment of the present disclosure; FIG. 2 shows a schematic structural diagram of a cross-section of a color film substrate according to an embodiment of the present disclosure; and FIG. 3 is a schematic diagram of pixel distribution of a color film substrate according to an embodiment of the present disclosure in an area A of FIG. 1. As shown in FIGS. 1, 2 and 3, the color film substrate includes a substrate base plate 1 and a black matrix layer 4. There are an irregular-shaped active area 2 and a peripheral region 3 surrounding the irregular-shaped active area 2 on the substrate base plate 1. The irregular active area 2 includes a plurality of first pixels 21 and at least one second pixel 22, and the second pixel 22 is closer to the peripheral region 3 relative to the first pixels 21, and a shape of a boundary line of each second pixel 22 close to the peripheral region 3 is the same as a shape of a boundary line of the peripheral region 3. The black matrix layer 4 includes a plurality of shielding structures, at least one of the plurality of shielding structures shields the second pixel 22 in a single-domain manner or at its circumference to form an opening region 201. When the shielding structure shields the second pixel 22 in the single-domain manner, an area of the opening region 201 formed by the second pixel 22 is greater than half an area of the second pixel 22; and when the shielding structure shields the second pixel 22 at the circumference, the opening region 201 formed by the second pixel 22 is concentrated in a middle portion of the second pixel 22.

The first pixels 21 are away from a boundary line of the irregular-shaped active area 2, and the second pixel 22 is close to the boundary line of the irregular-shaped active area 2. Both the first pixels 21 and the second pixel 22 may be located in a same layer of the substrate base plate 1. The first pixels 21 and the second pixel 22 may be arranged in the same layer. For example, the film layers included in the first pixels 21 and corresponding film layers in the second pixel 22 can be prepared by a same one patterning process.

It should be noted that because the second pixel 22 is closer to the peripheral region 3 relative to the first pixels 21, and the shape of the boundary line of each second pixel 22 close to the peripheral region 3 is the same as the shape of the boundary line of the peripheral region 3, when the boundary line of the peripheral region 3 is arc-shaped, zigzag-shaped or in other shapes, the shape of the second pixel 22 close to the peripheral region 3 is also arc-shaped, zigzag-shaped or in other shapes, that is, the second pixel 22 is an irregular-shaped pixel compared with the first pixels 21.

The black matrix layer 4 may be located at a side of each of the plurality of first pixels 21 and the at least one second pixel 22 away from the substrate base plate 1. In addition, the black matrix layer 4 can form an opening region 201 in a region where each pixel of the plurality of first pixels 21 and the at least one second pixel 22 is located, so that light emitted by each pixel can be emitted from the opening region 201, to realize normal display of the display apparatus.

In the embodiment of the present disclosure, the black matrix layer 4 includes a plurality of shielding structures, and at least one of the shielding structures shields the second pixel 22 in the single-domain manner or at the circumference. After the shielding structure shields the second pixel 22 in the single-domain manner or at the circumference, a boundary line of the formed opening region 201 close to the peripheral region 3 is the same as the boundary line of the peripheral region 3, and in this way, the opening region 201 formed by the second pixel 22 can be avoided from exceeding the irregular-shaped active area 2 of the color film substrate, and occurrence of burrs in graphs displayed at a boundary line of the irregular-shaped active area 2 can be avoided.

It should be noted that shielding in the single-domain manner can be understood as shielding at a single side of the pixel along a column direction of the pixel, so that the area of the opening region 201 formed by the second pixel 22 is greater than half of the area of the second pixel 22 when the shielding structure serve to shield the second pixel 22 in a single-domain manner, that is, the area of the second pixel 22 shielded by the shielding structure is less than half of the area of the second pixel 22, and a shielded position on the second pixel 22 is located at either side of a centerline in a row direction of pixels. In this way, the opening region 201 formed by the second pixel 22 can be made into an integral structure with the single-domain shielding, and the shielded position of the second pixel 22 by the shielding structure can be adjusted with change of lines at the boundary of the irregular-shaped active area 2 to adapt to the irregular-shaped active area 2 and to avoid burrs in the graphs displayed at the boundary of the irregular-shaped active area 2.

Shielding at the circumference can be that in a case where a small aperture ratio is required, such as when a size of the opening region 201 formed by the second pixel 22 in the column direction of the pixel is less than 10 microns, the shielding structure can shield in a circumferential direction of the second pixel 22, that is, edge positions of the second pixel 22 in the row direction of the pixels and edge positions of the second pixel in the column direction of the pixels are all shielded by the shielding structure, so that the opening region 201 formed by the second pixel 22 can be concentrated in a middle portion of the second pixel 22 by shielding at the circumference. In this way, a distance between upper and lower stops can be widened, and gray scales of the color film substrate are more accurate in a case of satisfying exposure resolution capacity. A row direction of the pixels is the direction shown by X in FIG. 1 and a column direction of the pixels is the direction shown by Y in FIG. 1.

For example, with a pitch in the row direction of the pixels being 30 microns, if a gray scale of a position of the irregular-shaped active area 2 close to the peripheral region 3 is 72 and the area of the opening region 201 formed by the second pixel 22 is 300 square microns, a pitch in the column direction of the pixels is 10 microns. However, because a minimum pixel pitch that the exposure machine can achieve needs to be greater than 14 microns, the exposure machine cannot meet the exposure resolution capacity and the gray scale cannot reach 72. However, due to the shielding at the circumference adopted in the embodiment of the present disclosure, a pitch in the row direction of the pixels can be adjusted to 20 microns, and a pitch in the column direction of the pixels can be 15 microns, so that the pitches in the row direction and the column direction of the pixels can meet the exposure resolution capacity of the exposure machine, and the gray scale can accurately reach 72.

In some embodiments, at least a part of a boundary of the irregular-shaped active area 2 is an arc, and a boundary line adjacent to the arc is tangent to the arc. In this way, the irregular-shaped active area 2 is partially in a regular arc structure, to present an arc rounded corner structure at four corners.

It can be seen from the above embodiments that in the embodiments of the present disclosure, since the black matrix layer 4 includes a plurality of shielding structures, at least one shielding structure of the plurality of shielding structures shields the second pixel 22 in the single-domain manner or at the circumference to form the opening region 201, and when the shielding structure shields the second pixel 22 in the single-domain manner, the area of the opening region 201 formed by the second pixel 22 is greater than half of the area of the second pixel 22; and when the shielding structure shields the second pixel 22 at the circumference, the opening region 201 formed by the second pixel 22 is concentrated in the middle portion of the second pixel 22, so that the middle portion of the second pixel serves as the opening region 201, and the opening region 201 is an integral structure, thereby avoiding burr phenomenon for the black matrix in the middle portion of the second pixel 22 when continuously arranged.

For the single-domain shielding, in some embodiments, as shown in FIG. 9, the second pixel 22 includes a plurality of first sub-pixels 221, at least one of the plurality of first sub-pixels 221 is an irregular-shaped sub-pixel, and after the shielding structure shields the first sub-pixels in the single-domain manner, areas of formed opening regions 201 are equal.

It should be noted that in the embodiment of the present disclosure, each second pixel 22 includes three first sub-pixels 221, which can be a red (R) sub-pixel, a green (G) sub-pixel and a blue (B) sub-pixel, respectively. A color of light emitted by the red sub-pixel is red, a color of light emitted by the green sub-pixel is green, and a color of light emitted by the blue sub-pixel is blue.

In addition, after the shielding structure shields the first sub-pixels 221 in the single-domain manner, the areas of the formed opening regions 201 are equal, so that brightness of light emitted by the first sub-pixels 221 is consistent, and color cast can be avoided.

Further, an overlapping part of a projection of the shielding structure on the substrate base plate 1 in a first direction and a projection of the irregular-shaped sub-pixel on the color film substrate in the first direction is of a first pattern, and an area of the first pattern is less than half an area of the irregular-shaped sub-pixel.

It should be noted that the overlapping part of the projection of the shielding structure on the substrate base plate 1 in the first direction and the projection of the irregular-shaped sub-pixel on the color film substrate in the first direction is of the first pattern, and the area of the first pattern is less than half the area of the irregular-shaped sub-pixel, that is, an area of an opening region 201 formed by the irregular-shaped sub-pixel is greater than half the area of the irregular-shaped sub-pixel, and a shielded position on the irregular-shaped sub-pixel is located at either side of the centerline in the row direction of the pixel. In this way, the opening region 201 formed by the irregular-shaped sub-pixel can be made into an integral structure by shielding in the single-domain manner, and the position of the irregular-shaped sub-pixel shielded by the shielding structure can be adjusted with change of lines at the boundary of the irregular-shaped active area 2 to adapt to the irregular-shaped active area 2 and avoid burrs in the graphs displayed at the boundary of the irregular-shaped active area 2.

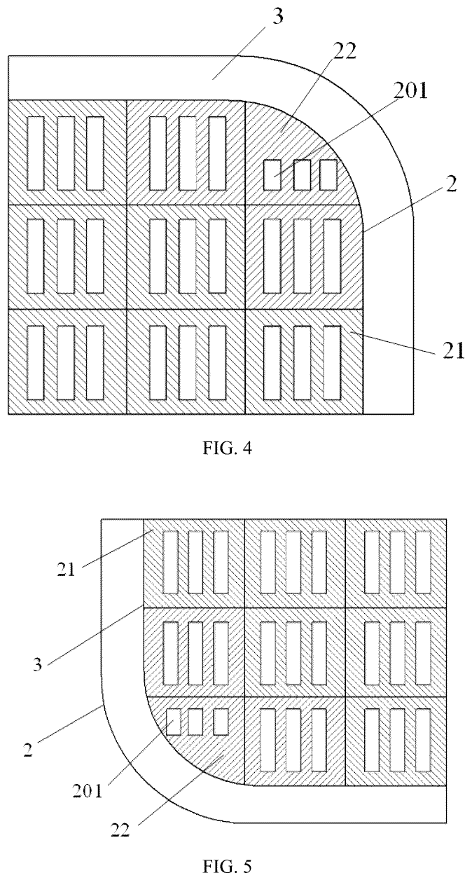

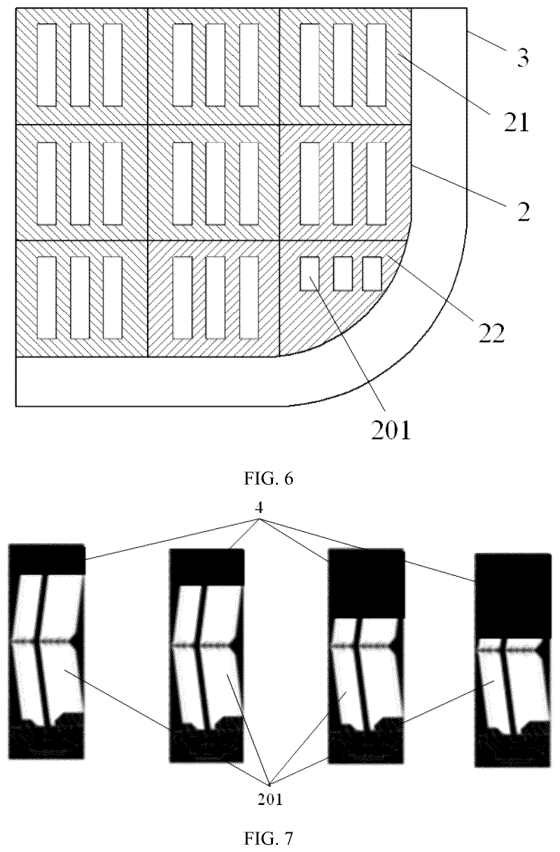

Specifically, a specific shielding method for the irregular-shaped sub-pixels located in different positions in different irregular-shaped active areas 2 can be as follows: as shown in FIG. 3, FIG. 4, FIG. 5 and FIG. 6, the overlapping part of the projection of the shielding structure on the substrate base plate 1 in the first direction and the projection of the irregular-shaped sub-pixel on the color film substrate in the first direction is a shielded part, and areas of shielded parts of the irregular-shaped sub-pixels 2 at different positions of the irregular-shaped active area are different, wherein the shielded position is a position of the irregular-shaped sub-pixel at either side of a centerline in a row direction of pixels.

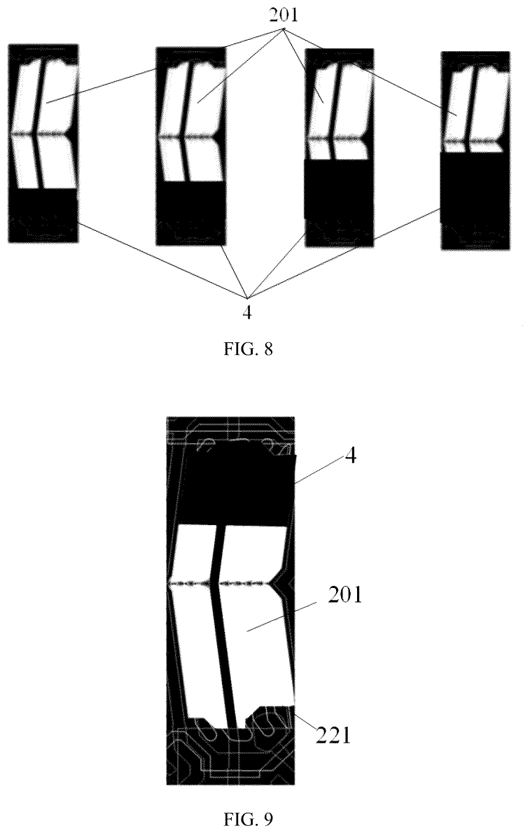

For example, as shown in FIG. 1, taking that the irregular-shaped active area 2 has four rounded corners as an example, for rounded corners at A and B, as shown in FIG. 7, the shielded position may be at a side where a centerline of the irregular-shaped sub-pixel in the row direction of the pixels is close to the peripheral region 3, as shown in FIG. 8, and for rounded corners at C and D, the shielded position may be a side where the centerline of the irregular-shaped sub-pixel in the row direction of the pixels is away from the peripheral region 3. With change of radian of the rounded corner, an area of the shielded part is constantly varied to adapt to arc transition of the rounded corner. For example, taking a half rounded corner of an area A as an example, an area of the shielded part changes gradually along a X direction in FIG. 1, and gray scales vary in a direction from an area B to the area A, that is, a size of a shielded part corresponding to the second pixel 22 with a gray scale of 254 along the column direction of the pixels is 4.5 microns, and a size of a shielded part corresponding to the second pixel 22 with a gray scale of 251 along the column direction of the pixel is 10.5 microns, a size of the shielded part corresponding to the second pixel 22 with a gray scale of 248 along the column direction of the pixel is 13.8 microns, and sizes of shielded parts corresponding to the second pixel 22 with a gray scale of 242, the second pixel 22 with a gray scale of 232, the second pixel 22 with a gray scale of 219, the second pixel 22 with a gray scale of 204, the second pixel 22 with a gray scale of 184, the second pixel 22 with a gray scale of 150, the second pixel 22 with a gray scale of 123, and the second pixel 22 with a gray scale of 72 are 18.8 microns, 26.2 microns, 35.2 microns, 45.2 microns, 56.6 microns, 73.6 microns, 90.2 microns, 91.1 microns, respectively.

To sum up, a gray scale of the irregular-shaped active area 2 can gradually transition, so that the opening region 201 formed by the second pixel 22 can be reduced synchronously with decreasing of a pixel area of the second pixel 22, thereby avoiding influence on actual display effect of the boundary of the irregular-shaped active area 2 and further improving the display effect.

In some embodiments, as shown in FIG. 11, the irregular-shaped active area 2 is provided with a blind hole 5, which is arranged close to the peripheral area, and a plurality of second sub-pixels are arranged around the blind hole 5. In this way, the blind hole 5 can enable normal access of light, to meet light requirements for photographing, shooting and others.

For provision of the blind hole 5, if all of the second sub-pixels around a peripheral side of the blind hole 5 are shielded by the shielding structure in a same shielding way, because an area of the blind hole 5 is small, opening regions 201 formed by the second pixels 22 are regularly arranged in a certain direction, which reduces adaptability to a contour of the blind hole 5, and thus occurs horizontal stripes, which affects the display effect of the color film substrate.

Based on this and alternatively, as shown in FIG. 11, the blind hole 5 may include a first part 51, a second part 52 and a third part 53, and the black matrix layer 4 at least includes a first shielding structure, a second shielding structure and a third shielding structure. The second part 52 is located between the first part 51 and the third part 53, and the first part 51 is close to the peripheral region 3. The first shielding structure shields a second sub-pixel disposed around the first part 51 to form a first opening region 201, the second shielding structure shields a second sub-pixel disposed around the second part 52 to form a second opening region 201, and the third shielding structure shields a second sub-pixel disposed around the second part 52 to form a third opening region 201. The first opening region 201 is located at a side of the second sub-pixel close to the peripheral region 3, the third opening region 201 is located at a side of the second sub-pixel close to the peripheral region 3, and the second opening region 201 is located in the middle portion of the second sub-pixel.

It should be noted that the first shielding structure shields the second sub-pixel disposed around the first part 51 to form the first opening region 201, the first opening region 201 is located at the side of the second sub-pixel close to the peripheral region 3, the second part 52 is located between the first part 51 and the third part 53, and the first part 51 is close to the peripheral region 3, and the first opening region 201 is located at the side of the second sub-pixel close to the peripheral region 3, the third opening region 201 is located at the side of the second sub-pixel close to the peripheral region 3, and the second opening region 201 is located in the middle portion of the second sub-pixel, so that a shielded part of a part of the blind hole 5 close to the peripheral region 3 is a side of the second pixel 22 close to the peripheral region 3. Because the second shielding structure shields the second sub-pixel disposed around the second part 52 to form the second opening region 201, a shielded part of a part of the blind hole 5 away from the peripheral region 3 is a side of the second pixel 22 away from the peripheral region 3. Because the third shielding structure shields the second sub-pixel disposed around the second part 52 to form the third opening region 201, the shielding part of the part of the blind hole 5 away from the peripheral region 3 is the middle portion of the second pixel 22. In this way, opening regions 201 formed by the second pixels 22 at different positions in the circumferential direction of the blind hole 5 are all arranged around the blind hole 5, so that adaptability between the opening regions 201 and the contour of the blind hole 5 can be improved, and thus the occurrence of the horizontal stripe can be avoided, and the display effect of the color film substrate at the blind hole 5 can be further improved.

In some embodiments, an area of the first part 51 is equal to an area of the second part 52. In this way, the first opening region 201 formed by the first shielding structure shielding the second sub-pixel disposed around the first part 51 and the second opening region 201 formed by the second shielding structure shielding the second sub-pixel disposed around the second part 52 are oppositely arranged, so that a distance between the blind holes 5 in an axial direction is equal, which is more conducive to improving the display effect of the color film substrate at the blind holes 5.

Further, the first part 51 and the second part 52 are both of a fan-shaped structure, and a central angle of the first part 51 and a central angle of the second part 52 are both between 76° and 90°. Optimum display effect of the color film substrate can be achieved at the blind hole 5. It should be noted that the central angle of the first part 51 and the central angle of the second part 52 can be determined according to a size of the blind hole 5, which is not limited in the embodiment of the present disclosure.

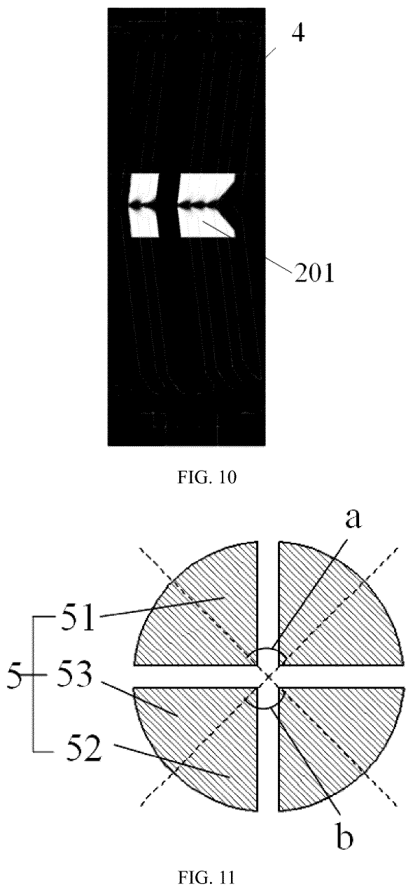

As for the shielding at the circumference, as shown in FIG. 10, the second pixel 22 includes a plurality of first sub-pixels 221, at least one of the plurality of first sub-pixels 221 is an irregular-shaped sub-pixel, and the shielding structures shields the first sub-pixels 221 at their circumference, and areas of the opening regions 201 formed by the first sub-pixels 221 are equal.

It should be noted that after the shielding structure shields the first sub-pixels 221 at the circumference, the areas of the opening regions 201 formed by respective first sub-pixels 221 are equal, so that brightness of light emitted by respective first sub-pixels 221 is consistent, and color cast can be avoided.

It should also be noted that shielding at the circumference can be that in a case where a small aperture ratio is required, for example, when a size of the opening region 201 formed by the irregular-shaped pixel in the column direction of the pixels is less than 10 microns, the shielding structure can shield the irregular-shaped pixel in the circumferential direction, that is, edge positions of the irregular-shaped pixel in the row direction of the pixels and edge positions of the irregular-shaped pixel in the column direction of the pixels are all shielded by the shielding structure, so that the opening region 201 formed by the irregular-shaped pixel can be concentrated in a middle portion of the irregular-shaped pixel by shielding at the circumference. In this way, a distance between upper and lower stops can be widened, and gray scales of the color film substrate are more accurate in a case of satisfying exposure resolution capacity.

For example, with a pitch in the row direction of the pixels being 30 microns, if a gray scale of the irregular-shaped active area 2 close to the peripheral region 3 is 72 and the area of the opening region 201 formed by the irregular-shaped pixel is 300 square microns, a pitch in the column direction of the pixels is 10 microns. However, because a minimum pixel pitch that the exposure machine can achieve needs to be greater than 14 microns, the exposure machine cannot meet the exposure resolution capacity and the gray scale cannot reach 72. However, due to the shielding at the circumference adopted in the embodiment of the present disclosure, a pitch in the row direction of the pixels can be adjusted to 20 microns, and a pitch in the column direction of the pixels can be 15 microns, so that the pitches in the row direction and the column direction of the pixels can meet the exposure resolution capacity of the exposure machine, and the gray scale can accurately reach 72.

In some embodiments, the color film substrate further includes a signal line 6, and the signal line 6 is connected to each of the second sub-pixels in the color film substrate.

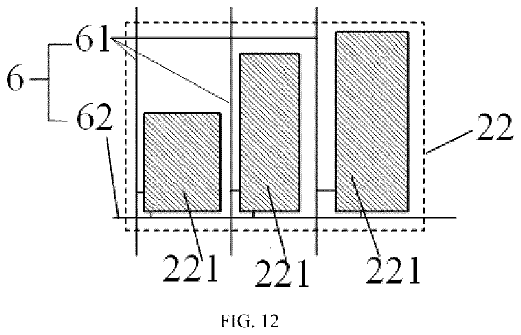

As shown in FIG. 12, the signal line 6 may include a plurality of data lines 61 and a plurality of gate lines, each of the data lines 61 may be connected to a column of sub-pixels and each of the gate lines may be connected to a row of sub-pixels.

It should be noted that a plurality of sub-pixels included in each pixel are arranged along the row direction of the pixels. Because there's difference between a length of the irregular-shaped sub-pixel included in the second pixel 22 in the row direction of the pixels and a length of the sub-pixel included in the first pixel 21 in the row direction of the pixels, at least one data line 61 of the plurality of data lines 61 can be in a bent shape in order to enable the data line 61 to connect the first sub-pixel 221 in the irregular-shaped pixel and the sub-pixel in the second pixel 22. In addition, at least one sub-pixel in a row of sub-pixels connected by the data line 61 in the bent shape is an irregular-shaped sub-pixel.

As another possible case, a plurality of sub-pixels included in each pixel are arranged along the column direction of the pixels. Because there's difference between a length of the second pixel 22 in the column direction of the pixels and a length of the first pixel 21 in the column direction of the pixels, at least one of the plurality of gate lines can be in a bent shape in order to enable the gate line to connect the first sub-pixel 221 in the first pixel 21 and the sub-pixel in the second pixel 22. In addition, at least one sub-pixel in a row of sub-pixels connected by the data line in the bent shape is an irregular-shaped sub-pixel.

As an alternative embodiment, the data line 61 includes a touch signal line 6. The touch signal line 6 is connected in a target second sub-pixel included in the second pixel 22. The target second sub-pixel is a blue sub-pixel.

It should be noted that because the touch signal line 6 is connected in the target second sub-pixel included in the second pixel 22, that is, the touch signal line 6 is only on blue color resistance of the blue sub-pixel, and because the blue color resistance is not considered in a traditional simulation method, simulation is performed according to color resistance of the red sub-pixel, which is then applied to the color resistance of the red sub-pixel, color resistance of the green sub-pixel and the color resistance of the blue sub-pixel, difference of coordinates of a white point can be caused, which is macroscopically expressed as color temperature difference. When this difference is serious, slight yellowing or bluing at the boundary of the irregular-shaped active area 2 can be caused, which affects the display effect.

Based on this, in the embodiment of the present disclosure, the touch signal line 6 is connected in the target second sub-pixel included in the second pixel 22, so that the color resistance of the red sub-pixel and the color resistance of the blue sub-pixel can be simulated respectively, the blue sub-pixel, the red sub-pixel and the green sub-pixel are always at a same aperture ratio, and thus brightness of the light emitted by respective first sub-pixels 221 is consistent, and color cast can be avoided.

In addition, for pixels with high gray scales, differential settings can be made for respective pixels with no burr. For a pixel with a gray scale greater than 246, an upper domain and a lower domain can be shielded at the same time, so that an opening region 201 formed by the pixel is concentrated in a middle portion of the pixel; and for a pixel with a gray scale less than 246, a single-domain shielding method can be adopted, that is, an upper domain or a lower domain of the pixel is shielded, so that an area of the opening region 201 formed by the pixel is greater than half the area of the second pixel 22, and thus when the gray scale is small, that is, when a shielded area is small, differential settings can be made for the pixel with no burr to achieve optimum display effect.

It can be seen from the above embodiments that in the embodiments of the present disclosure, since the black matrix layer 4 includes a plurality of shielding structures, at least one shielding structure of the plurality of shielding structures shields the irregular-shaped pixel in the single-domain manner or at the circumference to form the opening region 201, and when the shielding structure shields the irregular-shaped pixel in the single-domain manner, the area of the opening region 201 formed by the irregular-shaped pixel is greater than half of the area of the irregular-shaped pixel; and when the shielding structure shields the irregular-shaped pixel at the circumference, the opening region 201 formed by the irregular-shaped pixel is concentrated in the middle portion of the irregular-shaped pixel, so that the middle portion of the second pixel serves as the opening region 201, and the opening region 201 is an integral structure, thereby avoiding burr phenomenon for the black matrix in the middle portion of the irregular-shaped pixel when continuously arranged.

In a second aspect, a display substrate is further provided in the embodiment of the present disclosure, which includes the color film substrate described in any one of the embodiments in the first aspect. The display substrate has same beneficial effects as those of the color film substrate described above, which will not be repeatedly described in detail in the embodiment of the present disclosure.

In a third aspect, a display apparatus is provided in an embodiment of the present disclosure, which includes the display substrate described in the second aspect.

It should be noted that the display apparatus can be a mobile display apparatus such as a mobile phone, a tablet computer, a notebook computer, a palm computer, a vehicle-mounted display apparatus, a wearable device, an ultra-mobile personal computer (UMPC), a netbook or a personal digital assistant (PDA). The non-mobile display apparatus can be a personal computer (PC), a television (TV), an Automatic Teller Machine or a self-service machine, etc., which is not specifically limited in the embodiments of the present disclosure. The display apparatus has same beneficial effects as those of the color film substrate described above, which will not be repeatedly described in detail in the embodiment of the present disclosure.

It should be noted that the embodiments of the description are described in the mode of progression, each of the embodiments emphatically describes the differences from the other embodiments, and the same or similar parts of the embodiments may refer to each other.

Although alternative embodiments of the embodiments of the present disclosure have been described, once a person skilled in the art has known the essential inventive concept, he may make further variations and modifications on those embodiments. Therefore, the appended claims are intended to be interpreted as including the alternative embodiments and all of the variations and modifications that fall within the scope of the embodiments of the present disclosure.

Finally, it should also be noted that, herein, relation terms such as first and second are merely intended to distinguish one entity from another entity, and that does not necessarily require or imply that those entities have therebetween any such actual relation or order. Furthermore, the terms “include”, “comprise” or any variants thereof are intended to cover non-exclusive inclusions, so that articles or terminal devices that include a series of elements do not only include those elements, but also include other elements that are not explicitly listed, or include the elements that are inherent to such articles or terminal devices. Unless further limitation is set forth, an element defined by the wording “comprising a . . . ” does not exclude additional same element in the article or terminal device comprising the element.

The technical solutions of the present disclosure have been described in detail above. The principle and the embodiments of the present disclosure are described herein with reference to the particular examples. Moreover, for a person skilled in the art, according to the principle and the implementations of the present disclosure, the particular embodiments and the range of application may be varied. In conclusion, the contents of the description should not be understood as limiting the present disclosure.

1. A color film substrate, comprising:
a substrate base plate with an irregular-shaped active area and a peripheral region surrounding the irregular-shaped active area;
the irregular-shaped active area comprising a plurality of first pixels and at least one second pixel, wherein the second pixel is closer to the peripheral region relative to the plurality of first pixels, and a shape of a boundary line of each second pixel close to the peripheral region is the same as a shape of a boundary line of the peripheral region; and
a black matrix layer comprising a plurality of shielding structures, at least one of the plurality of shielding structures shielding the second pixel in a single-domain manner or at the circumference to form an opening region;
when the shielding structure shields the second pixel in the single-domain manner, an area of the opening region formed by the second pixel is greater than half an area of the second pixel; and
when the shielding structure shields the second pixel at the circumference, the opening region formed by the second pixel is concentrated in a middle portion of the second pixel.

2. The color film substrate according to claim 1, wherein the second pixel comprises a plurality of first sub-pixels, at least one of the plurality of first sub-pixels being an irregular-shaped sub-pixel, and with the shielding structure shielding the plurality of first sub-pixels in the single-domain manner, areas of opening regions formed by each of the first sub-pixel are equal.

3. The color film substrate according to claim 2, wherein an overlapping part of a projection of the shielding structure on the substrate base plate in a first direction and a projection of the irregular-shaped sub-pixel on the color film substrate in the first direction is a first pattern, and an area of the first pattern is less than half an area of the irregular-shaped sub-pixel.

4. The color film substrate according to claim 3, wherein the overlapping part of the projection of the shielding structure on the substrate base plate in the first direction and the projection of the irregular-shaped sub-pixel on the color film substrate in the first direction is a shielded part, and areas of shielded parts of the irregular-shaped sub-pixels at different positions of the irregular-shaped active area are different, wherein the shielded position is a position of the irregular-shaped sub-pixel at either side of a centerline in a row direction of pixels.

5. The color film substrate according to claim 3, wherein the irregular-shaped active area is provided with a blind hole;
wherein the blind hole is arranged close to the peripheral region, and the plurality of second sub-pixels is arranged around the blind hole.

6. The color film substrate according to claim 5, wherein the blind hole comprises a first part, a second part and a third part, and the black matrix layer at least comprises a first shielding structure, a second shielding structure and a third shielding structure;
the second part is located between the first part and the third part, and the first part is close to the peripheral region;
the first shielding structure shields the second sub-pixel disposed around the first part to form a first opening region, the second shielding structure shields the second sub-pixel disposed around the second part to form a second opening region, and the third shielding structure shields the second sub-pixel disposed around the second part to form a third opening region;
wherein the first opening region is located at a side of the second sub-pixel close to the peripheral region, the third opening region is located at a side of the second sub-pixel close to the peripheral region, and the second opening region is located in a middle portion of the second sub-pixel.

7. The color film substrate according to claim 6, wherein an area of the first part is equal to an area of the second part.

8. The color film substrate according to claim 7, wherein the first part and the second part are both of a fan-shaped structure, and a central angle of the first part and a central angle of the second part are both between 76° and 90°.

9. The color film substrate according to claim 1, wherein the second pixel comprises a plurality of first sub-pixels, at least one of the plurality of first sub-pixels is an irregular-shaped sub-pixel, and with the shielding structure shielding the plurality of first sub-pixels at the circumference, areas of opening regions formed by each of the first sub-pixels are equal.

10. The color film substrate according to claim 9, wherein a width of the opening region formed by the shielding structure shielding the second sub-pixel is less than 10 microns, wherein the width of the opening region is a size of the opening area along a column direction of the second sub-pixel.

11. The color film substrate according to claim 1, wherein at least a part of a boundary of the irregular-shaped active area is an arc, and a boundary line adjacent to the arc is tangent to the arc.

12. The color film substrate according to claim 2, wherein the color film substrate further comprises a signal line; and
the signal line is connected to each of the second sub-pixels in the color film substrate.

13. The color film substrate according to claim 12, wherein the signal line comprises a plurality of data lines and a plurality of gate lines; and
wherein each of the plurality of data lines is connected to a column of the second sub-pixels, and each of the plurality of gate lines is connected to a row of the second sub-pixels.

14. The color film substrate according to claim 13, wherein at least one of the plurality of data lines is in a bent shape, and at least one of the column of the second sub-pixels connected to the data line in the bent shape is the irregular-shaped sub-pixel.

15. The color film substrate according to claim 13, wherein at least one of the plurality of gate lines is in a bent shape, and at least one of the row of the second sub-pixels connected to the gate line in the bent shape is the irregular-shaped sub-pixel.

16. The color film substrate according to claim 13, wherein the data line comprises a touch signal line; and
the touch signal line is connected in a target second sub-pixel comprised in the second pixel, wherein the target second sub-pixel is a blue sub-pixel.

17. A display substrate, comprising the color film substrate according to claim 1.

18. A display apparatus, comprising the display substrate according to claim 17.

19. The display substrate according to claim 17, wherein the second pixel comprises a plurality of first sub-pixels, at least one of the plurality of first sub-pixels being an irregular-shaped sub-pixel, and with the shielding structure shielding the plurality of first sub-pixels in the single-domain manner, areas of opening regions formed by each of the first sub-pixel are equal.

20. The display substrate according to claim 19, wherein an overlapping part of a projection of the shielding structure on the substrate base plate in a first direction and a projection of the irregular-shaped sub-pixel on the color film substrate in the first direction is a first pattern, and an area of the first pattern is less than half an area of the irregular-shaped sub-pixel.
